(19) United States
(12) Patent Application Publication
(10) Pub. No.: US 2010/0149770 A1
(43) Pub. Date: Jun. 17, 2010

(54) Semiconductor stack package

(75) Inventors: Seung Wook Park, Suwon-si (KR); Jin Gu Kim, Suwon-si (KR); Jong Hwan Baek, Seoul (KR); Jong Yun Lee, Incheon-si (KR); Hyung Jin Jeon, Gunpo-si (KR); Young Do Kweon, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/453,272

(22) Filed: May 5, 2009

(30) Foreign Application Priority Data
Dec. 15, 2008 (KR) 10-2008-0127079

(51) Int. Cl. H01L 23/538

(52) U.S. Cl. 361/772; 361/783; 257/778; 257/E23.169

(57) ABSTRACT

The present invention relates to a semiconductor stack package including: a printed circuit board; a first semiconductor chip mounted on the printed circuit board; a second semiconductor chip mounted on the printed circuit board in parallel with the first semiconductor chip; a first rearrangement wiring layer positioned on the first semiconductor chip; a second rearrangement wiring layer which constitutes one circuit together with the first rearrangement wiring layer and is positioned on the second semiconductor chip; and a third semiconductor chip which is electrically connected to the first and second rearrangement wiring layers and of which both ends are separately positioned on the first and second semiconductor chips.

### CROSS-REFERENCE TO RELATED APPLICATIONS

This application claims the benefit of Korean Patent Application No. 10-2008-0127079 filed with the Korea Intellectual Property Office on Dec. 15, 2008, the disclosure of which is incorporated herein by reference.

### BACKGROUND OF THE INVENTION

1. Field of the Invention

The present invention relates to a semiconductor stack package; and, more particularly, to a semiconductor stack package to separately form rearrangement wiring layers constituting one circuit on at least two semiconductor chips and to include a stacked semiconductor chip which is stacked on the semiconductor chips and receives electric signals by being electrically connected to the rearrangement wiring layers separately formed on the semiconductor chips.

2. Description of the Related Art

A semiconductor package is a technology for effectively packaging a device used in an electronic product. Such a semiconductor package includes a chip packaging technology for modularizing semiconductor chips cut in ones by adhering them to a substrate and electrically connecting them.

In line with the recent trend toward miniaturization, lightness, and thinness of an electronic product, much development for miniaturization and thinness has been achieved even in the semiconductor package.

Specifically, as technologies regarding to a package structure of a semiconductor device to reduce an area for mounting on a motherboard, there have been developed a pin insertion type package such as a DIP(Dual Inline Package), a surface mounted package through a lead of an outer circumference such as an SOP(Small Outline Package), and a package having external output terminals positioned on a bottom surface of the package in a grid shape such as a BGA(Ball Grid Array).

In addition, as technologies to realize high-density assembly by reducing an area ratio of a package to a semiconductor chip, fine pitch of the external output terminal and miniaturization of the package have been promoted through fineness of a substrate wiring.

Further, there has been developed a multi-chip package for collecting a plurality of semiconductor chips and mounting them inside a single package, particularly for a semiconductor stack package for stacking and mounting a plurality of semiconductor chips in order to realize higher density assembly. Further, among the multi-chip packages, what realizes systematization by sealing a plurality of semiconductor chips each of which has a different function in a single package is called an SIP(System In package) of which development has been progressing.

An SIP technology is a technology where the semiconductor chips are horizontally or vertically mounted on a lead frame or a substrate to be made into one semiconductor package. Such a SIP technology is similar to a conventional MCM(Multi-Chip Module) technology in terms of the pursuing concept. Only, there is a difference therebetween in that the conventional MCM technology has a main concept that the semiconductor chips are horizontally mounted, while the SIP technology has a main concept that the semiconductor stack package is constructed by vertically stacking the semiconductor chips.

Meanwhile, because in most of general semiconductor chips, positions of pads are designed without considering SIP, i.e., the semiconductor stack package, if the semiconductor stack package is constructed by using the general semiconductor chips, a wiring substrate, i.e., a considerable number of wiring layers should be increased in the printed circuit board. At this time, it is possible to reduce the number of the wiring layers in the printed circuit board by stacking an interposer chip between the semiconductor chips.

However, as the conventional semiconductor stack package includes the interposer, the thickness of the semiconductor stack package is increased and a production cost of the semiconductor stack package is increased by needing an additional process to manufacture the interposer.

### SUMMARY OF THE INVENTION

The present invention has been invented in order to overcome the above-described problems and it is, therefore, an object of the present invention to provide a semiconductor stack package to separately form rearrangement wiring layers constituting one circuit on at least two semiconductor chips and include a stacked semiconductor chip which is stacked on the semiconductor chips and receives electric signals by being electrically connected to the rearrangement wiring layers separately formed on the semiconductor chips.

In accordance with one aspect of the present invention to achieve the object, there is provided a semiconductor stack package including: a printed circuit board; a first semiconductor chip mounted on the printed circuit board; a second semiconductor chip mounted on the printed circuit board in parallel with the first semiconductor chip; a first rearrangement wiring layer positioned on the first semiconductor chip; a second rearrangement wiring layer which constitutes one circuit together with the first rearrangement wiring layer and is positioned on the second semiconductor chip; and a third semiconductor chip which is electrically connected to the first and second rearrangement wiring layers and of which both ends are separately positioned on the first and second semiconductor chips.

Herein, the first and second semiconductor chips can be wire bonded to the printed circuit board.

Further, the third semiconductor chip can be wire bonded to the first and second rearrangement wiring layers.

Further, the third semiconductor chip can be flip chip bonded to the first and second rearrangement wiring layers.

Further, the third semiconductor chip can be electrically connected to the printed circuit board via the first and second rearrangement wiring layers.

Further, the first to third semiconductor chips can be electrically connected to each other.

Further, the semiconductor stack package can further include a fourth semiconductor chip mounted on the printed circuit board in parallel with the first and second semiconductor chips; and a third rearrangement wiring layer on the fourth semiconductor chip to constitute one circuit together with the first and second rearrangement wiring layers.

Herein, the third semiconductor chip can be connected to the third rearrangement wiring layer and positioned after being extended onto the fourth semiconductor chip.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a plane-view illustrating a semiconductor stack package in accordance with a first embodiment of the present invention;

FIG. 2 is a cross-sectional view taken along line I-I′ shown in FIG. 1;

FIG. 3 is a cross-sectional view illustrating a semiconductor stack package in accordance with a second embodiment of the present invention; and

FIG. 4 is a cross-sectional view illustrating a semiconductor stack package in accordance with a third embodiment of the present invention.

### DETAILED DESCRIPTION OF THE PREFERABLE EMBODIMENTS

Hereinafter, embodiments of the present invention will be described in detail with reference to the accompanying drawings illustrating a semiconductor stack package. The following embodiments are provided as examples to allow those skilled in the art to sufficiently appreciate the spirit of the present invention. Therefore, the present invention can be implemented in other types without limiting to the following embodiments. And, for convenience, the size and the thickness of a device can be overdrawn in the drawings. The same components are represented by the same reference numerals hereinafter.

Further, although in accordance with embodiments of the present invention, semiconductor chips provided in a semiconductor package include a plurality of bonding pads and wires, for convenience of explanation, only a few bonding pads and wires are illustrated.

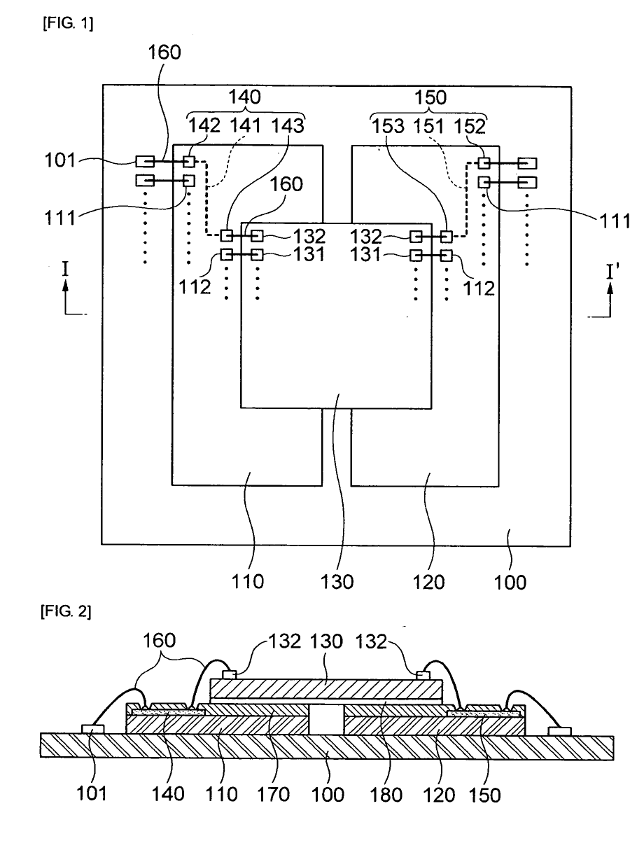

FIG. 1 is a plane-view illustrating a semiconductor stack package in accordance with a first embodiment of the present invention and FIG. 2 is a cross-sectional view taken along line I-I′ shown in FIG. 1.

Referring to FIGS. 1 and 2, the semiconductor stack package in accordance with the embodiment of the present invention includes a printed circuit board 100, first and second semiconductor chips 110 and 120 mounted on the printed circuit board 100, first and second rearrangement wiring layers 140 and 150 separately formed on the first and second semiconductor chips 110 and 120, and a third semiconductor chip 130 of which both ends are positioned on the first and second semiconductor chips 110 and 120 respectively.

The printed circuit board 100 can include a circuit layer which is formed on an insulating layer. Herein, the circuit layer includes substrate pads 101 which are electrically connected to the first to third semiconductor chips 110, 120 and 130. Further, the substrate pads apply electric signals to the first to third semiconductor chips 110, 120 and 130 from an outside by being electrically connected to the outside. In addition, although not shown in the drawings, the wire layers can electrically connect the first and second semiconductor chips 110 and 120 to each other.

The first and second semiconductor chips 110 and 120 are positioned on the printed circuit board 100 in parallel. Herein, the first and second semiconductor chips 110 and 120 can include first chip pads 111 to be electrically connected to each of the substrate pads 101. At this time, the substrate pads 101 and the first chip pads 111 can be bonded through wires 160.

In addition, the first and second semiconductor chips 110 and 120 can include second chip pads 112 which are electrically connected to the following third semiconductor chip 130 through wires 160. In other words, the second chip pads 112 can be electrically connected to third chip pads 131 of the third semiconductor chip 130 through the wires 160.

The first and second rearrangement wiring layers 140 and 150 constitutes one circuit. At this time, the third semiconductor chip 130 can be electrically connected to the printed circuit board 100 via the first and second rearrangement wiring layers 140 and 150.

Specifically, the first rearrangement wiring layer 140 includes a first wiring pattern 141 and a first rearrangement pad 142 and a first contact pad 143 which are positioned at both ends of the first wiring pattern 141 respectively. Herein, the first rearrangement pad 142 can be electrically connected to a substrate pad 101 through a wire 160.

Further, the first contact pad 143 can be electrically connected to a fourth chip pad 132 of the third semiconductor chip 130 through a wire 160. Namely, one portion of the third semiconductor chip 130 can be electrically connected to the printed circuit board 100 via the first rearrangement wiring layer 140.

Like the first rearrangement wiring layer 140, the second rearrangement wiring layer 150 includes a second wiring pattern 151 and a second rearrangement pad 152 and a second contact pad 153 which are positioned at both ends of the second wiring pattern 151 respectively. Herein, the second rearrangement pad 152 can be electrically connected to a substrate pad 101 through a wire 160.

Further, the second contact pad 153 can be electrically connected to a fourth chip pad 132 of the third semiconductor chip 130 through a wire 160. In other words, another portion of the third semiconductor chip 130 can be electrically connected to the printed circuit board 100 via the second rearrangement wiring layer 150.

Consequently, the one portion of the third semiconductor chip 130 can be electrically connected to the printed circuit board 100 via the first rearrangement wiring layer 140 and the other portion of the third semiconductor chip 130 can be electrically connected to the printed circuit board 100 via the second rearrangement wiring layer 150.

Accordingly, since the third semiconductor chip 130 stacked on the first and second semiconductor chips 110 and 120 can be prevented from being directly wire bonded to the printed circuit board 100, it is possible to reduce lengths of the wires 160. Further, as the chip pads as final external connection units of the third semiconductor chip 130 are rearranged by the first and second rearrangement wiring layers 110 and 120, the substrate pads 101 electrically connected to the third semiconductor chip 130 can be also rearranged. In other words, since a separation interval between the substrate pads 101 can be adjusted, it is possible to prevent contact between the wires 160 connected to the substrate pads 101.

Further, the rearrangement wiring layers 140 and 150 for rearranging the chip pads of the third semiconductor chip 130 should have at least an area wider than the third semiconductor chip 130. However, since the rearrangement wiring layers 140 and 150 are separately formed on the first and second semiconductor chips 110 and 120, it is not needed to consider sizes of the first and second semiconductor chips 110 and 120 which are positioned at a lower part of the third semiconductor chip 130, thereby improving the degree of freedom of selection of the semiconductor chips provided on the semiconductor stack package in accordance with the embodiment of the present invention.

Further, the first to third semiconductor chips 110, 120 and 130 are electrically connected to each other. In other words, the first and second semiconductor chips 110 and 120 are electrically connected to each other through the printed circuit board 100 and the first and third semiconductor chips 110 and 130 and the second and third semiconductor chips 110 and 130 are electrically connected to each other through wire-bonding. As a result, the semiconductor chips provided on the semiconductor stack package in accordance with the embodiment of the present invention, i.e., the first to third semiconductor chips 110, 120 and 130 can transmit electric signals to each other.

In addition, the semiconductor stack package can further include insulating patterns 170 which cover the rearrangement wiring layers 140 and 150 and are positioned on the first and second semiconductor chips 110 and 120 respectively.

Further, the semiconductor stack package can further include an adhesion member 180 between the first and second semiconductor chips 110 and 120 and the third semiconductor chip 130. At this time, the third semiconductor chip 130 can be stably fixed on the first and second chips 110 and 120 by the adhesion member 180.

Therefore, the semiconductor stack package in accordance with the embodiment of the present invention can reduce the number of the wiring layers of the printed circuit board in integrating the pads of the stacked semiconductor chip and reduce the lengths of the wires in wire bonding the stacked semiconductor chip by including the rearrangement wiring layers between the semiconductor chips, thereby enhancing electric reliability.

Further, since the rearrangement wiring layers are thinner than the conventional interposer, it is possible to achieve thinness of the semiconductor stack package.

Further, since the rearrangement wiring layers are separately formed on the semiconductor chips which are positioned in parallel, it is possible to increase the degree of freedom of selection of the semiconductor chips without the need to consider the sizes of the semiconductor chips which are positioned at the lower part.

Hereinafter, a semiconductor stack package in accordance with a second embodiment of the present invention will be described with reference to the accompanying drawing. Herein, the same components and reference numerals thereof as those of the semiconductor stack package in accordance with the first embodiment are given except that a semiconductor chip is stacked through flip chip bonding and overlapping explanation will not be repeated.

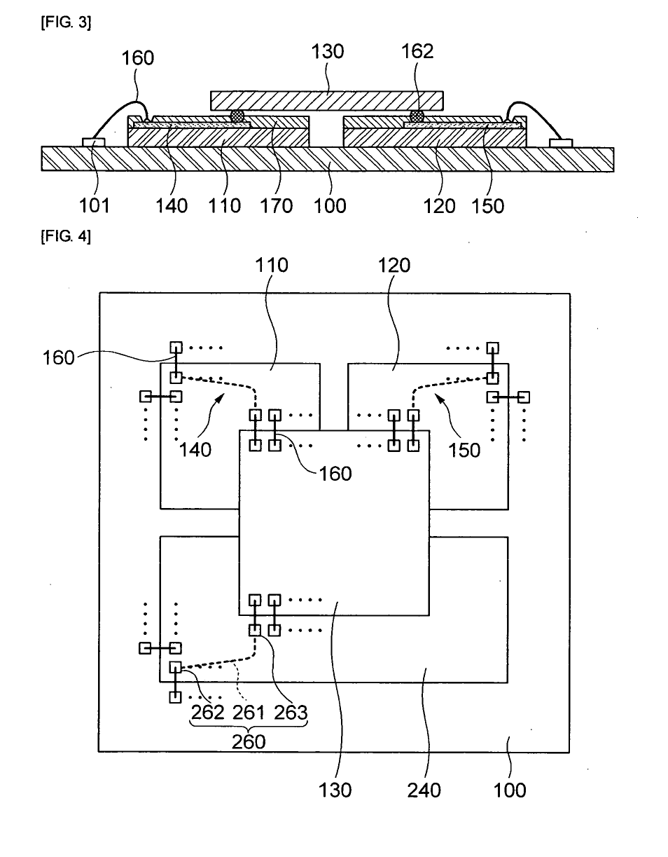

FIG. 3 is a cross-sectional view illustrating a semiconductor stack package in accordance with a second embodiment of the present invention.

Referring to FIG. 3, the semiconductor stack package in accordance with the embodiment of the present invention includes a printed circuit board 100, a first semiconductor chip 110 mounted on the printed circuit board 100, a second semiconductor chip 120 positioned in parallel with the first semiconductor chip 110 and mounted on the printed circuit board 100, a first rearrangement wiring layer 140 positioned on the first semiconductor chip 120, a second rearrangement wiring layer 150 which constitutes one circuit together with the first rearrangement wiring layer 140 and is positioned on the second semiconductor chip 120, and a third semiconductor chip 130 which is electrically connected to the first rearrangement wiring layer 140 and the second rearrangement wiring layer 150 and of which both ends are positioned on the first and second semiconductor chips 110 and 120.

Herein, the third semiconductor chip 130 can be electrically connected to the printed circuit board 100 via the first and second rearrangement wiring layers 140 and 150.

At this time, the third semiconductor chip 130 can be electrically connected to the first and second rearrangement wiring layers 140 and 150 through flip chip bonding. For instance, one portion of the third semiconductor chip 130 can be electrically connected to the first rearrangement layer 140 by soldering a bump ball 162. Further, the other portion of the third semiconductor chip 130 can be electrically connected to the second rearrangement layer 150 by soldering a bump ball 162.

In addition, in order to secure reliability of electric contact between the third semiconductor chip 130 and the first and second rearrangement wiring layers 140 and 150, although not shown in the drawing, an under fill can be provided to cover at least a connection portion between the third semiconductor chip 130 and the first and second rearrangement wiring layers 140 and 150.

Therefore, in the semiconductor stack package in accordance with the embodiment of the present invention, connection between the semiconductor chips can be sufficiently executed by applying a flip chip bonding method without performing the wire bonding.

Hereinafter, a semiconductor stack package in accordance with a third embodiment of the present invention will be described with reference to the accompanying drawing. Herein, the same components and reference numerals thereof as those of the semiconductor stack package in accordance with the first embodiment are given except for a fourth semiconductor chip and overlapping explanation will not be repeated.

FIG. 4 is a cross-sectional view illustrating a semiconductor stack package in accordance with a third embodiment of the present invention.

Referring to FIG. 4, the semiconductor stack package in accordance with the embodiment of the present invention includes a printed circuit board 100, a first semiconductor chip 110 mounted on the printed circuit board 100, a second semiconductor chip 120 positioned in parallel with the first semiconductor chip 110 and mounted on the printed circuit board 100, a first rearrangement wiring layer 140 positioned on the first semiconductor chip 120, a second rearrangement wiring layer 150 which constitutes one circuit together with the first rearrangement wiring layer 140 and is positioned on the second semiconductor chip 120, and a third semiconductor chip 130 which is electrically connected to the first rearrangement wiring layer 140 and the second rearrangement wiring layer 150 and of which both ends are positioned on the first and second semiconductor chips 110 and 120.

In addition, the semiconductor stack package can further include a fourth semiconductor chip 240 which is mounted on the printed circuit board 100 in parallel with the first and second semiconductor chips 110 and 120. At this time, the third semiconductor chip 130 can be extended onto the fourth semiconductor chip 240.

A third rearrangement wiring layer 260 can be further positioned on the fourth semiconductor chip 240. At this time, the third rearrangement wiring layer 260 can constitute one circuit together with the first and second rearrangement wiring layers 140 and 150.

The third rearrangement wiring layer 260 can include a third wiring pattern 261 and a third contact pad 262 and a third rearrangement pad 263 which are positioned at both ends of the third wiring pattern 261 respectively. At this time, the third contact pad 262 is electrically connected to a fourth chip pad 132 of the third semiconductor chip 130 through a wire 160 and the third rearrangement pad 263 can be electrically connected to a substrate pad 101 of the printed circuit board 100 through a wire 160. In other words, one portion of the third semiconductor chip 130 can be electrically connected to the printed circuit board via the third rearrangement wiring layer 260.

Therefore, in the semiconductor stack package in accordance with the embodiment of the present invention, since the rearrangement wiring layers for rearranging the chip pads of the stacked semiconductor chip are separately formed on two or more semiconductor chips which are positioned at the lower part, it is not needed to consider the sizes of the semiconductor chips, thereby enhancing the degree of freedom of selection of the semiconductor chips.

As described above, the semiconductor stack package of the present invention can reduce the number of the wiring layers of the printed circuit board in integrating the pads of the stacked semiconductor chip and reduce the lengths of the wires in wire bonding the stacked semiconductor chip by including the rearrangement wiring layers between the stacked semiconductor chips, thereby enhancing the electric reliability.

Further, it is possible to achieve the thinness of the semiconductor stack package by forming the rearrangement wiring layers to be thinner than the conventional interposer.

Further, it is possible to increase the degree of freedom of the selection of the semiconductor chips without the need to consider the sizes of the semiconductor chips positioned at the lower part by separately forming the rearrangement wiring layers on at least two semiconductor chips positioned in parallel.

As described above, although the preferable embodiments of the present invention have been shown and described, it will be appreciated by those skilled in the art that substitutions, modifications and changes may be made in this embodiment without departing from the principles and spirit of the general inventive concept, the scope of which is defined in the appended claims and their equivalents.

What is claimed is:

1. A semiconductor stack package comprising:
a printed circuit board;
a first semiconductor chip mounted on the printed circuit board;
a second semiconductor chip mounted on the printed circuit board in parallel with the first semiconductor chip;
a first rearrangement wiring layer positioned on the first semiconductor chip;
a second rearrangement wiring layer which constitutes one circuit together with the first rearrangement wiring layer and is positioned on the second semiconductor chip; and
a third semiconductor chip which is electrically connected to the first and second rearrangement wiring layers and of which both ends are separately positioned on the first and second semiconductor chips.

2. The semiconductor stack package of claim 1, wherein the first and second semiconductor chips are wire bonded to the printed circuit board.

3. The semiconductor stack package of claim 1, wherein the third semiconductor chip is wire bonded to the first and second rearrangement wiring layers.

4. The semiconductor stack package of claim 1, wherein the third semiconductor chip is flip chip bonded to the first and second rearrangement wiring layers.

5. The semiconductor stack package of claim 1, wherein the third semiconductor chip is electrically connected to the printed circuit board via the first and second rearrangement wiring layers.

6. The semiconductor stack package of claim 1, wherein the first to third semiconductor chips are electrically connected to each other.

7. The semiconductor stack package of claim 1, further comprising:
a fourth semiconductor chip mounted on the printed circuit board in parallel with the first and second semiconductor chips; and
a third rearrangement wiring layer on the fourth semiconductor chip to constitute one circuit together with the first and second rearrangement wiring layers.

8. The semiconductor stack package of claim 7, wherein the third semiconductor chip is connected to the third rearrangement wiring layer and positioned after being extended onto the fourth semiconductor chip.
